(19) United States
(12) Patent Application Publication
(10) Pub. No.: US 2023/0373336 A1
(43) Pub. Date: Nov. 23, 2023

(54) METHOD FOR OPTIMISED MANAGEMENT OF THE SEQUENCING OF VEHICLE CHARGING ON A LOCAL ELECTRICITY GRID

(71) Applicant: IFP Energies nouvelles, RUEIL-MALMAISON CEDEX (FR)

(72) Inventors: Paul MALISANI, RUEIL-MALMAISON CEDEX (FR); Philippe POGNANT-GROS, RUEIL-MALMAISON CEDEX (FR); Jiamin ZHU, RUEIL-MALMAISON CEDEX (FR)

(21) Appl. No.: 18/030,131

(22) PCT Filed: Oct. 1, 2021
(86) PCT No.: PCT/EP2021/077105

§ 371 Date: Apr. 4, 2023

(30) Foreign Application Priority Data
Oct. 14, 2020 (FR) FR2010494

(51) Int. Cl. B60L 53/64; B60L 53/63; B60L 53/62; G01R 31/367

(52) U.S. Cl. CPC B60L 53/64; B60L 53/63; B60L 53/62; G01R 31/367

(57) ABSTRACT

The invention relates to charging vehicles connected to a charging infrastructure. The charging infrastructure may have a micro-grid possibly including renewable energy producers. The invention provides a method and optimized management accounting for the variety of vehicle batteries, and a number of charging stations smaller than the number of vehicle parking spaces. The present invention relates to an urban electricity micro-grid, focused on an aspect of local electricity production and use, and on an aspect of electricity purchase and resale optimization.

### CROSS REFERENCE TO RELATED APPLICATIONS

Reference is made to PCT/EP2021/077105 filed Oct. 1, 2021, and French Patent Application No. 2010494 filed Oct. 14, 2020, which are incorporated herein by reference in their entirety.

### BACKGROUND OF THE INVENTION

### Field of the Invention

The present invention relates to the field of charging vehicles connected to a charging infrastructure. The charging infrastructure may be an electric micro-grid possibly including renewable energy producers, such as a micro-grid also referred to as local electric grid. The present invention relates to an urban electricity micro-grid, focused on local electricity production and use, and on electricity purchase and resale optimization.

The technical field of the present invention also relates to a method and to hardware and software devices enabling optimized management of an electrified vehicle (electric or plug-in hybrid vehicle) charging infrastructure. The charging infrastructure can comprise at least one electric micro-grid connected to the public distribution network and charging stations. These stations can be associated with a device for automatic connection of the vehicles to the stations. This affords the advantage of pooling a station for several parking spaces for several vehicles, but raises a question of charging sequencing of when to disconnect the station from one vehicle to another.

### BACKGROUND OF THE INVENTION

### Description of the Prior Art

Several methods have been developed to solve this problem. Among these methods, the following can notably be mentioned:

Patent application WO-2019/126,806 A1 describes a method and a device for sizing a charging infrastructure and for vehicle charge control. Two approaches are presented, with one being deterministic and the other being stochastic. To control charging, a constrained optimization is performed over a 24-hour horizon. However, this method does not take account for a priori knowledge on the vehicle batteries to optimize charging sequencing and control strategy.

Patent application WO-2019/109,084 A1 describes the control of one or more simultaneous charging infrastructures using a quadratic optimization criterion associated with each charging infrastructure. The control is all of the infrastructures from centralized control laws. Only the states of charge and the departure time of the vehicles are taken into account. There is no account of a priori knowledge on the vehicle batteries for optimizing charging sequencing and control strategy.

Patent application US-2017/0,036,560 A1 describes predictions of charging power and energy necessary for electrical vehicles on a mission. These predictions allow future charging needs to be distributed within a charging station network. The vehicles can be directed to charging stations with available power and energy (charging time).

Patent application US-2015/0,042,278 A1 describes a robotic arm and control thereof, capable of plugging a charging cable into the charging plug of a vehicle. This arm can cover up to 4 parking spaces and successively charge 4 vehicles. A parked vehicle detection device allows defining the user's contract type and managing the type of charge accordingly, including V2G (Vehicle to Grid), in cases when the vehicle supplies energy to the grid.

Furthermore, the methods described in the above patent applications are not designed for optimizing charging sequencing when the number of charging stations is less than the number of parking spaces.

### SUMMARY OF THE INVENTION

The invention is a method and an optimized management system accounting for the variety of vehicle batteries and of a number of charging stations smaller than the number of vehicle parking spaces. Indeed, the prior art involves shortcomings that the present invention solves by accounting for vehicle battery characteristics which optimize charging sequencing and control strategy, a possible local renewable energy supply for economic optimization, and for providing charging sequencing when the number of stations is smaller than the number of vehicles.

The invention provides a method and an optimized management system accounting for the variety of vehicle batteries and a number of charging stations smaller than the number of vehicle parking spaces. Generally speaking, the present invention relates to an urban electricity micro-grid, focusing on an aspect of local electricity production and use, and on an aspect of electricity purchase and resale optimization.

### BRIEF DESCRIPTION OF THE DRAWINGS

Other features and advantages of the method according to the invention will be clear from reading the description hereafter of embodiments given by way of non-limitative example, with reference to the accompanying figures wherein:

FIG. 1 schematically illustrates the constituent elements of a micro-grid according to an embodiment of the invention;

FIG. 2 illustrates the variation of the internal resistance of the open-circuit voltage of the battery u_{ocv} as a function of the state of charge (SOC) according to an example embodiment;

FIG. 3 illustrates the variation of the internal resistance of the battery r_{c} as a function of the state of charge (SOC) according to an example embodiment;

FIG. 4 illustrates the variation of the internal resistance of the battery maximum charging power p_{c}⁺ as a function of the state of charge (SOC) according to an example embodiment;

FIG. 5 illustrates the normalized battery dynamics f_{c} as a function of the SOC and the lambda (L) charge rate according to an example embodiment with the higher the grey level intensity, the higher the dynamics;

FIG. 6 illustrates the variation of the efficiency η of the battery as a function of the SOC and of the lambda (λ) charge rate according to an example embodiment with the higher the grey level intensity, the higher the efficiency, i.e. close to 1;

FIG. 7 illustrates a combinatorial representation of integer variables according to an embodiment of the invention;

FIG. 8 illustrates the depth-first search method by exploring primarily the best child of each generation according to an embodiment of the invention;

FIG. 9 illustrates the strategy that consists in switching at nearly each time step of the charging of vehicles according to an example embodiment; and

FIG. 10 illustrates the state of charge of the vehicle batteries as a function of time according to the example embodiment of FIG. 9.

### DETAILED DESCRIPTION OF THE INVENTION

The present invention relates to an optimal charging scheduling for electric vehicles or plug-in hybrid vehicles on a smart vehicle charging infrastructure which is also referred to as vehicle charging station. Optimal charging scheduling is understood to be charging sequencing, in other words, the order in time of the charging of vehicles.

In the rest of the description, the term “vehicle” designates any type of vehicle equipped with at least one battery that can be recharged, notably an electric vehicle or a plug-in hybrid vehicle. The vehicle type may notably be a motor vehicle, a truck, a two-wheeler, a construction vehicle, a forklift truck, a bicycle, etc. In addition, the expression “parked vehicle” designates any vehicle present in a parking space.

According to the invention, the smart charging infrastructure comprises:
at least one charging station connected to an electric distribution network;
at least two parking spaces for a vehicle; and
at least one connection device for connecting a vehicle parked in one of the parking spaces and a charging station, the connection device is suited for connecting a parked vehicle to the station whatever the parking space among several parking spaces, preferably among all the parking spaces.

According to the invention, the vehicle charging infrastructure is a charging infrastructure with more parking spaces than charging stations. Thus, the infrastructure enables connection between a vehicle parked in a parking space and a charging station. The charging infrastructure can automatically switch the vehicle to be charged among the vehicles parked in the parking spaces, by use of the connection device.

The problem is in recharging vehicles using a number of charging stations smaller than the number of vehicles. These charging stations can be connected to the vehicles one after the other, the vehicles being parked in different parking spaces. The objective is to recharge the batteries of the vehicles before they leave the car park while minimizing a criterion, such as the charging cost for example. It may therefore be assumed that the vehicle arrival time, the battery capacity, its state of energy and its departure time are provided. Under these circumstances, the charge problem is a deterministic problem and it is dealt within the wrong way. However, an approach might be considered for using the algorithm presented also in a stochastic context.

The invention mainly relates to the method of determining the charging sequence of vehicles and their charging control.

Some embodiments of the invention are based on different devices of hardware and software type, and they have the following respective functions:
recognition by image processing of the parked vehicle, then of its battery type through a database and parameters reflecting the electric, energy and thermal behavior thereof, which is referred to as a priori knowledge on the batteries;
selection by the user of a specific charging service for their vehicle through a human-machine interface and real-time control of charging and discharging speeds of V2G type vehicles, optimizing an electricity purchase and sale cost structure to the benefit of the infrastructure operator, in the presence or not of RE (Renewable Energy) production of a photovoltaic canopy type for example;
selection of the right time for a vehicle to be automatically or manually connected to a specific station, for example a slow or fast charging station, etc.;
the forecast over a time horizon of the total energy and power of the storage system connected to the infrastructure, with this system for example of the mobile batteries of the vehicles on the road, which vehicles provide geolocation data; and
the charging sequencing aspect when the number of stations is smaller than the number of parked vehicles (co-charging).

The elements listed below can be used independently of one another or in combination to combine the effects thereof.

According to an embodiment of the invention, the infrastructure can also comprise automatic vehicle recognition, preferably optical recognition of the registration plate of the vehicle when the vehicle arrives in one of the parking spaces. These optical devices can be of CCD camera type connected to a shape recognition and image interpretation device. Any other recognition type is also possible, for example recognition of the shape of the vehicle or of distinct parts of the vehicle, such as the bumper, or any combination of parts of the vehicle such as, for example, the shape of the exterior mirrors and the vehicle type: coupe, sedan, station wagon (break or estate vehicle), van, etc. Other alternative automatic vehicles recognition techniques can implement identification technologies using RFID, radio waves, infrared, field sensors, etc.

According to an embodiment of the invention, the infrastructure can also comprise remote vehicle communication. The purpose is to initiate and to carry out communication notably with any approaching vehicle, in order to transmit any relevant information for identification of a vehicle and to provide information on a state of the battery, and possibly any contractual information.

According to an embodiment of the invention, at least one of the types of connection to a vehicle can be implemented automatically, without human intervention. In this embodiment of the invention, an automated device can connect one or more vehicles to a charging station. The connection can comprise a motorized arm beneath the vehicle or above the vehicle. Guidance of this connection type can be achieved using a magnetic head. The connection type can also be a mobile robot, notably using wheels, which moves the electrical cord from one vehicle to another and the base of the station. According to the type of connection used and to the positioning of each vehicle in the parking spaces relative to the other vehicles and to the station to which the process decides to be connected, the time required for achieving connection can vary. Including these connection times in a constrained cost function minimization allowing the result thereof to be refined.

According to the embodiment of the invention, the charging sequencing is determined upon each identification of a new vehicle, the identification taking place upon arrival of an electrical vehicle in one of the parking spaces or prior to arrival, through the remote connection type or according to a schedule. Indeed, when the arrival of a new vehicle is announced remotely or when it arrives at the charging station, the charging sequencing of the other vehicles which is already connected or whose arrival is scheduled, may be affected. Charging scheduling can be useful notably when it is desired to charge vehicles belonging to a fleet of vehicles that carry out pre-planned tasks or that do tours whose durations are known in advance. One can also mention here vehicles transporting goods or people over routes of predetermined time or distance such as, for example, buses, shuttles, taxis, delivery vehicles transporting goods to a factory or a city, cleaning robots, etc.

According to an embodiment of the invention, upon each vehicle arrival, the smart charging station can retrieve the state of energy of the vehicle and the departure time of the vehicle. Using this data, the charging station can calculate an optimal charging schedule for the vehicles.

According to an embodiment of the invention, a materialized human/machine interface can be used, preferably at least one of being in a station, and/or dematerialized, preferably in form of an application. In the case of a physical station, the interface can comprise a screen, a keyboard and payment device. In the case of a dematerialized interface, an application for a computer type device or a smartphone can be used.

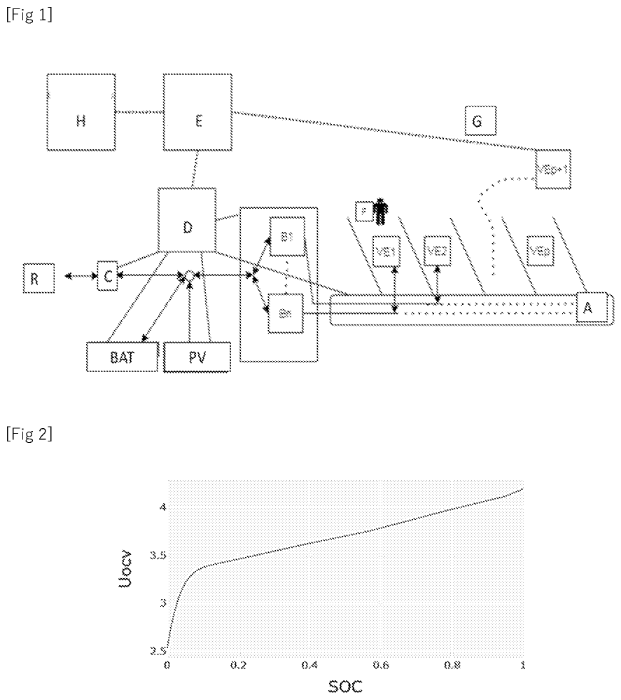

The diagram of FIG. 1 describes the constituent elements of a micro-grid (infrastructure) according to an embodiment of the invention and their interaction as follows:
B1, . . . Bn: charging stations of any type (any type, AC, DC),
VE1, . . . VEp: parked electric vehicles;
VEp+1: electric vehicle in remote communication;
A: connections for electric connection of the stations to the vehicles;
PV: (optional element) electricity production from renewable sources such as photovoltaic, wind power, etc.;
BAT: (optional element) stationary electricity storage systems of lithium battery type;
C: (optional element) system of metering the electrical power consumed or produced by the micro-grid;
D: electronic device and local software for controlling the stations and their connection to the vehicles;
E: (optional element) communications for providing, data collection and remote calculation of cloud computing type;
F: (optional element) human-machine interface enabling the user to input a charging service;
G: (optional elements) communications between a vehicle on mission and remote computations;
H: (optional element) database for battery models; and
R: public electricity distribution network.

Nomenclature:
x^{λ}: state of charge of the vehicle with charge rate λ
p_{c}⁺: maximum charging power
f_{c}: dynamics of the state of charge of the battery
ρ: battery efficiency
u_{ocv}: open-circuit voltage of the battery
r_{c}: internal resistance of the battery
price: electricity price
nₓ: number of vehicles to be charged
n_{b}: maximum number of charging stations
p_{c,i}⁺: maximum charging power of vehicle i
t_{f}: scheduling horizon
λᵢ: control variable representing the charge rate of vehicle i
cᵢ: integer control variable representing the allowable maximum charging power for vehicle i
Eᵢ⁺: maximum state of charge of vehicle i
PC([0, t_{f}], R; ΔT): set of piecewise constant functions of [0, t_{f}] in R, constant in the interval [kΔT, (k+1)ΔT)
ΔT: minimum connection time of a vehicle to a charging station
P_{c}={p₁, p₂, . . . , pₙ_{_{b}}}: set of maximum charging powers
Pₛ: maximum power available for the entire charging station
t_{0,k}: earliest time to connect vehicle k to a station
t_{f,k}: latest time to disconnect vehicle k from a station
x_{0,k}: initial state of charge of the battery of vehicle k
x_{f,k}: desired final state of charge for vehicle k
MS(C_{ad}, m_{c}): multiset with C_{ad} a set referred to as support and m_{c} a function of C_{ad} in the set of natural numbers, referred to as multiplicity.

The micro-grid accommodates parked electric vehicles VE1 to VEp connectable to one of the stations B1 to Bn of the charging infrastructure by use of an electrical connection means A. Vehicles VEp+1 are for example on mission and have not arrived at the charging infrastructure and can communicate with the infrastructure communications in order to predict a future vehicle arrival. These vehicles are also provided with remote communications allowing to transmit, over time, information related to the position and to the state of the battery. The vehicles can optionally be provided with a bidirectional charger enabling discharge of their battery to the micro-grid.

The charging stations can be bidirectional or not, on an alternating or direct current basis, referred to as slow or fast station. The stations preferably meet the OCPP standard and above, which enables power control from device D.

Device A allows automatic connection of a station to a vehicle.

According to an embodiment, a computer program for optimizing sequencing and charging of the vehicles can be described as a predictive control management strategy whose general operation is described hereafter:

On arrival of a vehicle:
1) Device D detects its presence, for example by cameras and recognition software. It can read the registration plate or recognize the shape of the vehicle and thereby determine the brand manufacturer, the model and the year of manufacture. Access to data on the battery is made possible by a database of the Argus™ type in France, and information of the type: battery technology, capacity, power, can be retrieved. Access to such a database can be achieved through communication device E connected to communication device D, then to a battery database H in order to obtain the parameters of a battery charging model. This model can be used for calculation of the charging power sequencing and determination. The advantage of this sequence is that the vehicles are processed in a specific manner or considering a dedicated battery model from database H which is hosted in the communication device E, which is used in the vehicle sequencing and charging optimization program. The user may have the opportunity to enter their charging criteria and a specific charging service by use of a human-machine interface F, notably by inputting at least one of the following parameters:
   charging station disconnection time, interms of departure time of the vehicle;
   charging options in terms of minimum time charging, emergency charging; and
   authorization to use the vehicle battery to supply power to the grid, etc.

In summary: On arrival of a vehicle, the new battery is added to the list of batteries present in the charging system and integrated into the optimization model. The state of charge of the vehicle, the battery model and the disconnection time can be recovered by the optimization program. If the departure time is not defined, a predefined average duration can be assigned before the vehicle departure such as, 8 hours for example.
2) The optimization program described below allows generation of the charging schedule of each vehicle, that is which station each vehicle is to be connected to and the power to be drawn from the station for each vehicle, with all of it for the entire residence time of the vehicle at the charging stations.
3) The schedule is followed (charging of the vehicles is performed according to the determined sequencing) until the arrival of a new vehicle, where step 1 is repeated.

In addition to the algorithm developed within the context of this invention to calculate this optimal schedule, one of the main benefits of the method is to consider that charging of the vehicles is performed in a smart charging station, provided by a device allowing the various vehicles connected to the stations to be charged without any human intervention. This makes it possible to have a number of charging stations smaller than the number of parking spaces while charging of the vehicles thus parked is guaranteed.

The invention thus relates to a control method for an infrastructure. See FIG. 1 for example, for charging electric vehicles VE1, VE2, . . . , VEp and VEp+1 with each electric vehicle being equipped with at least one battery. In other words, a vehicle can have one or more batteries or cell modules. In some cases, a vehicle can have modules or batteries with different characteristics and, in this case, each module is accounted for separately or optimized battery management strategies are applied. The infrastructure comprises at least one charging station B1, . . . , Bn connected to an electric distribution network R, at least two parking spaces for the vehicles and at least one connection device for electrical connection of the at least one charging station to at least one electric vehicle parked in one of the at least two parking spaces. Of course, if there is no parked vehicle, the method charges no vehicle. The number of charging stations is smaller than the number of parking spaces. In other words, there are more parking spaces than charging stations. The method of the invention implements:
1) a set of parameters of the electric vehicle and of its battery selected notably from among an unsatisfactory charging penalty, a service provision agreement, an initial charge level for the at least one battery, a required charge level at the end of charging of the at least one battery and modeling of the at least one battery. The following list of parameters can be preferably used: vehicle identification number, latest connection time, earliest disconnection time, parameters of an electrochemical behavior model of the battery: open-circuit voltage u_{ocv}, internal resistance r_{c} and limit power p_{c}⁺. The vehicle can therefore be associated with a contractual aspect of “service level agreement” (SLA), “service agreement” or “service commitment” type that may for example stipulate that a case of partial or unsatisfactory charging can be associated with a penalty. The initial charge level can be detected by the station, it can be remotely communicated or it can be part of a provisional charge schedule for vehicles belonging to a fleet for example. The charge level required at the end of charging can be, by default, the maximum level, but it may also be a level considered as satisfactory by the customer, notably if other parameters have to be taken into account, for example if the charging time is constrained, if the electricity price exceeds a threshold or if the penalty relative to other contracts is higher. The proposed modeling of the at least one battery can be based on the electrochemical behavior of the battery. This model is intended to be both simple enough for use in an optimal control context but complex enough to represent the behavior of a real battery. Such a model can be represented by open-circuit voltage u_{ocv}, internal resistance r_{c} and limit power p_{c}⁺ parameters. Preferably, the set of parameters of the electric vehicle comprises at least one battery modeling so as to model charging of the battery, in order to implement an optimal battery charge, according to the battery type and to these characteristics (electric vehicle batteries can be of different types and have different characteristics);
2) a set of parameters of the infrastructure notably selected from among a waiting time in the queue among the vehicles parked in the parking spaces, electric characteristics of the at least one charging station (maximum power and/or efficiency for example), the number of operational charging stations, a connection time for the at least one connection to a vehicle. The connection of the at least one connection to a vehicle can be considered to be instantaneous in a first approach of the algorithm, negligible considering for example a minimum 15-minute charging sequence. However, for greater precision, this element can also be included in the calculation, notably if the charging sequence durations are reduced, in which case the connection time is no longer at least one of negligible and when several connection types are possible, for example by a person, a robotic arm, etc. In this case, the time required by the various types of connection of a vehicle to the station can be included in the calculation to refine the result thereof; and
3) a set of electrical power parameters (also referred to as set of electricity parameters) notably selected among sizing the electrical network, sizing of the locally available electrical power, a maximum threshold of power drawn by all of the stations, a selling price for the electricity from the electrical network (i.e. the price of the electricity supplied by at least one charging station to the electrical network) and a purchase price (that is the price of the electricity supplied by the electrical network to at least one charging station) that may vary over time.

The method of the invention relates to the charging of electric vehicles according to a charging sequencing comprising at least one step of charging at least one electric vehicle, the sequencing being determined by constrained cost function minimization of at least one parameter of each of the three sets of parameters detailed above.

According to an embodiment of the invention, a source of electricity, notably renewable, of solar or wind power type, preferably locally produced, can further be controlled. Alternatively, this energy source can use biogas, hydroelectric power or any other renewable energy source. It is however not excluded to use a micro electric power plant, a cogeneration or a even a nuclear micro plant, fuelled by hydrocarbons or any fossil fuel.

According to an implementation of the invention, the evolution model of the energy contained in the battery (referred to as battery charge model) can be written with the following formula:

$${\dot{x}}^{λ} = ( - {u}_{o c v} ( {x}^{λ} ) + \sqrt{\frac{{u}_{o c v}^{2} ( {x}^{λ} ) + 4 {r}_{c} ( {x}^{λ} ) {p}_{c}^{+} ( {x}^{λ} ) λ}{2 {r}_{c} ( {x}^{λ} )}} ) \frac{{u}_{o c v} ( {x}^{λ} )}{2 {r}_{c} ( {x}^{λ} )}$$

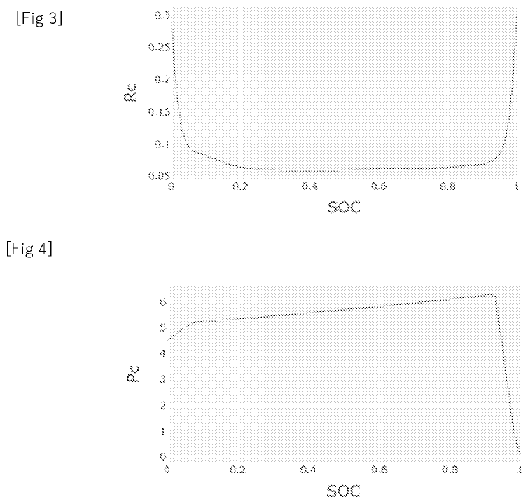

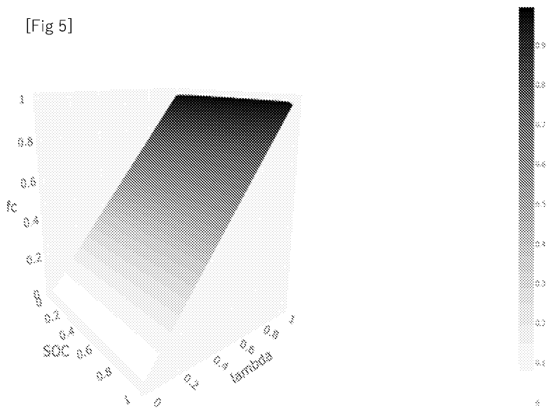

Functions u_{ocv}, r_{c} and p_{c}⁺ are polynomial functions of the battery energy defined by interpolation from experimental data as represented in FIGS. 2 to 4. FIG. 5 shows the battery dynamics f_{c}, which can be expressed as:

\dot{x}^{λ}=f_{c}(x^{λ}, λ)

The efficiency can thus be defined as follows:

$$η ( {x}^{λ} , λ ) = \frac{{f}_{c} ( {x}^{λ} , λ )}{{p}_{c}^{+} ( {x}^{λ} ) λ}$$

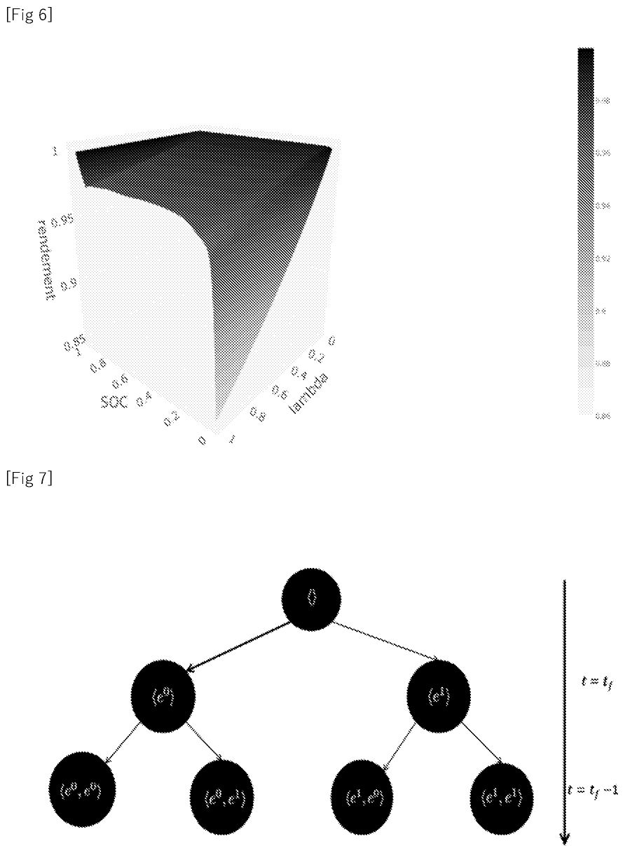

Efficiency η is shown in FIG. 6. Other battery charge models may be used. These models describe mathematically the power limits, the efficiency according to the battery type, the state of charge and the temperature of the battery. However, for greater precision, it is advisable to use an aging model in form of a time-, current-, state of charge- and temperature-dependent capacity loss.

According to this embodiment of the invention, battery modeling is expressed as a function of an open-circuit voltage of the battery and of an internal resistance of the battery, and the sequencing implements a charge model suited to the battery modeling. Such modeling can use the operating principle shown in FIG. 2, which illustrates the variation of the internal resistance of open-circuit voltage u_{ocv} of the battery as a function of the state of charge (SOC). It is notably observed that, for SOC<0.1, the voltage is particularly low, which may require suitable charge parameterization. Consequently, the required charge power can be so high that the charge management mechanism needs to take it into account in order to optimize charging of such a battery.

According to an embodiment of the invention, the following steps can be carried out upon identification of a new vehicle or departure of a charging electric vehicle:
a. determining at least one of the elements of the set of parameters of the infrastructure
b. determining at least one of the elements of the set of parameters of the electrical energy
c. for each at least one electric vehicle:
   i. determining at least one of the elements of the set of parameters of the electric vehicle
   ii. determining at least one control parameter for each of the at least one charging step of the charging sequencing, the control parameter comprising at least one duration and electrical power value for charging at least one electric vehicle, and the electrical power can be positive in case of charging and negative in case of discharging
d. carrying out each of the at least one electric vehicle charging step of the charging sequencing, by successively connecting each at least one electric vehicle parked in one of the parking spaces to a charging station.

According to an embodiment of the invention, a charging sequencing can be optimized depending on profiles of the costs of purchase and sale of the electrical energy of the network, of the electrical energy and the energy stored in at least one of a stationary battery and at least one electric vehicle battery. Preferably, this energy can be produced locally, in geographic proximity to the device. According to this embodiment, at least one electric vehicle battery can further be controlled as a source of electricity. It is a battery of a vehicle connected to a station that can be used as a source of electricity in a variety of circumstances. However, a stationary battery can also be used to provide greater flexibility in managing the purchase and sale of electricity. For example, electricity can be sold in case of a high demand on the public network. One may also consider the case where it would be economically interesting to use the energy provided by at least one of a stationary battery and a vehicle battery and for charging another vehicle battery and another stationary battery.

According to an embodiment of the invention, the sequencing can be adjusted depending on usual traffic conditions, and according to a schedule. Readjustment according to the traffic allows optimizing charging of the vehicles already parked in anticipation of the arrival of other vehicles, and it also allows to optimize the charging cost.

According to an embodiment of the invention, the method can also be adjusted depending on at least one of statistical and stochastic profiles of at least one element of the sets of parameters.

According to an embodiment of the invention, the method can also be adjusted depending on at least one machine learning logic which is preferably located in the cloud.

Calculation of this optimal scheduling is a mixed non-linear optimal control problem, that is with continuous and discrete time variables. The complexity of the problem lies in that only some vehicles can be recharged at the same time, because there are more parking spaces than charging stations. The continuous-time optimal control part is due to the fact that the electric batteries the vehicles are equipped with are dynamic systems.

Finally, a first start may be from the premise that the charging sequences occur at constant time steps, which provides a discrete temporal part.

According to an embodiment of the invention, the constrained minimization of the cost function is performed by a tree exploration method and preferably by a Branch and bound method. The tree exploration method is a decision-making tool representing a set of choices in the graphical form of a tree. The complete sequences of the various possible decisions are located at the ends of the branches (the “leaves” of the tree) and they represent the decisions made at each step.

According to an embodiment of the invention, the general methodology can consist in managing the entire part of the algorithm using a Branch and bound algorithm, which in turn can use a constrained non-linear optimal control algorithm to calculate the optimal path in the branch and the related tree to be explored.

The Branch and bound algorithm is notably described in the following documents:
C. H. Papadimitriou, K. Steiglitz. Combinatorial Optimization, Algorithms and Complexity, chapter 18, 2nd edition, Dover edition 1998; and
B. Korte, J. Vygen, Combinatorial Optimization, Theory and Algorithms, chapter 5 and 21, 2nd edition, Springer 2001.

In other words, this invention relates to a method of calculating an optimal charging schedule for an electric vehicle at a charging station capable of automatically switching an electric vehicle. The presented methodology is preferably based on a Branch and Bound strategy allowing the global optimum to be calculated. The methodology presented in one embodiment relies heavily on an optimal control solver based on Pontryagin's maximum principle allowing fast calculation of a good lower limit of the global optimal cost at each node of the tree. However, in order to operate to its full potential, this algorithm can run on a cluster so that, upon expansion of a node, its children can be computed in parallel. Preferably, the uncertainties on the departure time and arrival time of the electric vehicles can also be taken into account. A progressive recovery approach could be considered to use the algorithm presented in a stochastic context.

A Branch and Bound algorithm is a generic method of solving combinatorial optimization problems. Combinatorial optimization finds a point minimizing a function, referred to as cost, in a discrete set. A naive way to solve this problem is to enumerate all the solutions to the problem, to compute the cost for each one, then to give the minimum. It is sometimes possible to avoid enumerating solutions that are known, from analysis of the problem properties, to be bad solutions that is solutions that cannot be the minimum. The Branch and Bound method is notably used for solving NP-complete problems, that is problems considered difficult to solve efficiently, which makes it a method intended for operational research problems.

Throughout this exploration, at each node, the Branch and Bound algorithm fulfills various tasks:
bounding: computation of the optimal solution to a relaxed problem according to the path from the current node to the root of the tree. For a node of depth k, the relaxed problem is an optimization problem where k integer variables have been defined. This relaxed optimization problem provides the algorithm with a lower bound on the cost,
branching: once the node bounding part has been computed, the branching part can be performed. Branching of a node has two mutually exclusive actions which are:
exploration: if the lower bound associated with the current node of depth k is smaller than the upper bound of the optimal cost, the node is worth exploring and the children of the current node are computed. Computing the children creates one child per possible value of the discrete variables, for each child. Thus, the path connecting the root of the tree to any node represents the sequence in retrograde time of the values taken at any time by the discrete variables,
pruning: if the tree from the current node is not worth exploring, that is if the best optimal solution of any node of the tree from the current node is greater than the cost of an admissible trajectory for the problem posed, the branch is pruned and will not be explored.

The efficiency of a Branch and Bound approach therefore requires both a good relaxed problem, that is a continuous problem that best approximates the integer values problem, and a good exploration method, that is a method that mainly explores the nodes located on the optimal path of the tree.

The Branch and Bound method has been adapted in order to obtain a good compromise between precision, speed and robustness. These three aspects are detailed hereafter:
1. Precision: The Branch and Bound method, based on a systematic exploration of the tree of possibilities, allows obtaining the global optimum of the problem.
2. Speed: The tree search heuristics (modified depth-first search and best-first search) allow an efficient tree search by rapidly obtaining a very good upper bound on the optimal cost. This bound being rather thin, it enables very quick elimination of a very large number of branches of the tree to be explored. Using indirect optimal control methods allows fast computation of the optimal solution to the relaxed problem, knowing the optimal solution of the parent node. Indeed, these methods, numerically sensitive, make it possible to find very rapidly the optimal solution to the problem, on condition of a good solver initialization. Now, the optimal solution to the relaxed problem of the parent node is a very good initial solution for the current node.
3. Robustness: The collocation methods used for solving the optimal control problem allowing to compute the lower bound of the optimization problem corresponding to each node allow to obtain a good compromise between performance and robustness, between fast shooting methods, not robust at initialization, and slow direct methods, robust at initialization.

The goal of this method explores as few nodes as possible to obtain the optimal solution. The solution in this embodiment of the invention obtains as rapidly as possible a good optimal cost upper bound in order to eliminate all the branches whose relaxed optimal cost is greater than this bound. A leaf (an end) of the tree therefore needs to be reached as quickly as possible. FIG. 7 illustrates the combination of a problem where, at each time step, the integer variable can take 2 values e⁰ or e¹. The root of the tree corresponds to the zero depth where no integer variable has been fixed. The nodes of depth 1, that is the nodes directly connected to the root, correspond to the different values that can be taken by the integer variable at the time t_{f} (two in this case). Thus, each node of depth k corresponds to a scenario where the integer variable has been fixed in the time steps ranging between t_{f}−k and t_{f}, and all of the nodes of depth k represent all the possible scenarios of the integer variable in the time steps ranging between t_{f}−k and t_{f}. Then, the leaves of the tree (i.e. the nodes of depth t_{f}) correspond to all the possible scenarios for the integer variable in the time steps ranging between t_{f}−k and t_{f}. A depth-first search of the tree is thus performed. At each depth, exploring the node with the smallest relaxed optimal cost is performed. Once a leaf of the tree has been reached (i.e. all the integer variables are fixed), a first solution satisfying all the constraints, which is therefore an upper bound of the optimal cost, is obtained. It is then optionally possible to switch to a search method prioritizing the nodes having the smallest relaxed optimal cost until there are no more interesting nodes to be explored.

The constrained minimization of the cost function according to an embodiment of the invention using a Branch and Bound method is written in the form:

$${min}_{{λ}_{i} , {c}_{i}} {\int }_{0}^{{t}_{f}} {\sum }_{i = 1}^{{n}_{x}} price ( t ) {p}_{c , i}^{+} ( {x}^{{λ}_{i}} ( t ) ) {λ}_{i} ( t ) d t$$

This formula includes arbitration between the price of electrical energy for purchase and sale and the impact on battery wear. The battery operating model can be written as follows:

\dot{x}^{λ}^{ᵢ}(t)=f_{c,i}(x^{λ}^{ᵢ}(t), λ(t))

It is reminded that the right-hand side of FIG. 5 shows the battery dynamics f_{c}, which can be expressed according to Formula 2.

According to the invention, minimization of the cost function depends on predefined parameters among the sets of parameters of the vehicle, the infrastructure and the electrical energy. Thus, sequencing accounts for the constraints related to the vehicle, the infrastructure and the electrical energy for optimizing charging sequencing.

According to an embodiment depending on the predefined parameters of the sets of parameters of the vehicle, the infrastructure and the electrical energy, this cost function minimization can be written under the following constraints:

$$\begin{matrix}{\dot{x}}^{{λ}_{i}} ( t ) = {f}_{c , i} ( {x}^{{λ}_{i}} ( t ) , {λ}_{i} ( t ) ) \\ {x}_{i}^{λ} ( t ) ∈ [ 0 , {E}_{i}^{+} ] \\ {λ}_{i} ( t ) ∈ [ 0 , 1 ] \\ {λ}_{i} ( t ) {p}_{c , i}^{*} ( {x}^{{λ}_{i}} ( t ) ) \leq {c}_{i} ( t ) \\ {c}_{i} ∈ PC ( [ 0 , {t}_{l} ] , ℝ ; Δ T ) \\ {( {c}_{i} ( t ) , … , c \text{?} ( t ) )}^{T} ∈ perm ( {n}_{i} ; MS ( C \text{?} , {m}_{C} ) ) \\ MS ( C \text{?} , {m}_{C} \text{?} ) = … \\ \{ \begin{matrix}MS ( {P}_{n} , {m}_{c} ) \text{?} MS ( \{ 0 \} , n \text{?} - {n}_{b} ) & \text{?} n \text{?} > {n}_{b} \\ MS ( {P}_{c} , {m}_{c} ) & otherwise\end{matrix} \\ {\sum }_{i} {λ}_{i} ( t ) {p}_{c , i}^{*} ( {x}^{{λ}_{i}} ( t ) ) \leq {P}_{s}\end{matrix}$$

$$\text{?} \text{indicates text missing or illegible when filed}$$

The tree exploration each node in bounding the optimal cost and in generating its children has been covered. To completely describe the Branch and Bound algorithm, the exploration part of this algorithm, that is in which order the nodes will be explored, needs to be specified.

According to an embodiment, constrained minimization of the cost function is performed using a tree exploration method and preferably a Branch and Bound method coupled with optimal control methods under state and control constraints. This allows the evaluation of the constrained minimization of the cost function to be optimized.

Depth-First Search Strategy

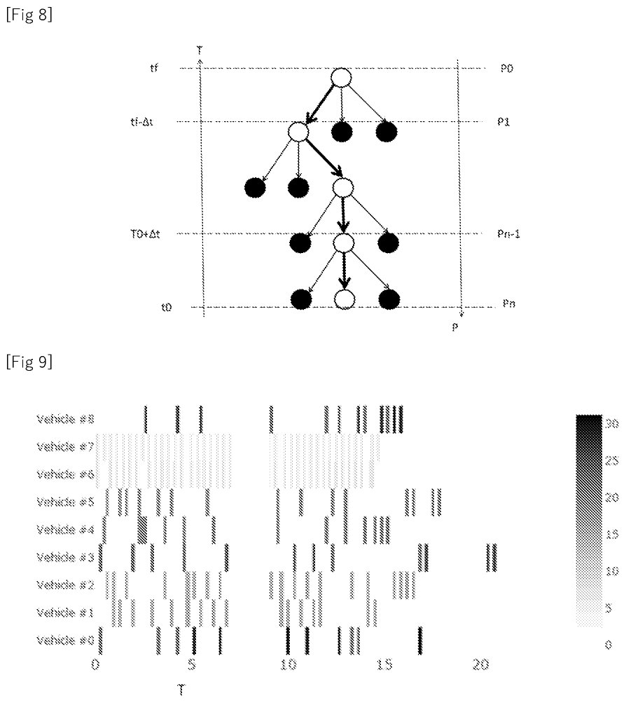

According to an embodiment, in order to have an efficient tree size, it is very important to obtain a good upper bound on the optimal cost so that any relaxed solution whose lower bound is greater than this upper bound can be pruned. The better the upper bound, the faster the algorithm. However, the upper limits of the optimal cost are computed only on the leaves of the tree. It is therefore very important to reach a leaf as rapidly as possible. An exploration technique of depth-first search type can therefore be used. FIG. 8 illustrates the depth-first search method by exploring the best child per generation. The best child is represented by a hollow circle. The depth-first search technique places the generated children of a node in a stack, then explores the node on top of the stack. This procedure guarantees that the currently explored node is always one step deeper than the previous one, and that a leaf node is reached after exploring t_{f} generations. However, in order to obtain a good upper bound on the optimum cost, the generated nodes are stacked in decreasing order of their relaxed optimal cost. This guarantees that the depth-first search method follows the path of the best children. Indeed, a node is explored, then its best child is explored, then the best child of its best child, and so on. These heuristics allow the algorithm to rapidly find a good upper bound. In addition, using a retrograde time strategy to define the integer variable often makes it possible to find the optimal solution at the end of the depth-first search procedure. FIG. 8 shows, in the right part, an arrow P describing the order of the steps of the process, starting with step P0 and ending with step Pn, which corresponds to the tree leaf. At each step, the relaxed optimal cost of all the possible children of the current node is computed and the best child node, in white, is determined, and this step is repeated for the best child node displayed in white. The left part of the figure shows the charging time scale with t0 the time when charging sequencing starts, and tf the final time when charging sequencing must be completed. This time scale is in the reverse order of the steps of the method. For this method, step PO corresponds to final time tf, and step P1 to time tf-Δt (Δt representing the minimum duration of a charging sequence), step Pn-1 corresponds to time t0+Δt, and step Pn corresponds to time t0. Thus, this method optimizes sequencing, starting from the desired state of charge. This method therefore guarantees an optimization allowing obtaining the desired state of charge for the parked vehicles.

Best-First Search Strategy

Once the depth-first search strategy has reached a leaf, a good upper bound is available. To complete optimization, one can ensure that there is no remaining node that could potentially be the root of a tree containing the optimal solution in one of its leaves. To rapidly reach this step, the exploration method is now a best-first search method, that is the node with the smallest relaxed optimal cost is explored as a priority. The data structure behind this best-first search is a priority queue enabling access to the best node of the stack immediately.

Presentation of the Interior Penalty Approach:

The lower bound problem of the Branch and Bound algorithm can be solved using a penalized interior in an optimal control approach. This method relaxes the constraints by increasing the cost by using interior penalty functions.

This relaxation depends on the sequence of parameters converging to 0. When this sequence converges to 0, the solution to the relaxed optimal solution converges to the solution to the original problem. The penalized problem can be written as follows, in form of an objective function M to be minimized:

$${min}_{λ ∈ {Λ}_{0}} M ( λ , {E}^{k} , ε ) = {\int }_{{t}_{0}}^{{t}_{f}} [ {\sum }_{i} price \cdot {p}_{c , i}^{+} ( {x}^{{λ}_{i}} ) {λ}_{i} + ε {\sum }_{i} ( {γ}_{x} ( - {x}^{{λ}_{i}} ) + {γ}_{x} ( {x}^{{λ}_{i}} - {E}_{i}^{+} ) ) + ε {\sum }_{i} {γ}_{λ} ( {λ}_{i} ) + ε {\sum }_{i} {γ}_{x} ( {λ}_{i} {p}_{c , i}^{+} ( {x}^{{λ}_{i}} ) - {C}_{i}^{r} ( t ; {E}^{k} ) ) + ε {γ}_{x} ( {\sum }_{i} {λ}_{i} {p}_{c , i}^{+} ( {x}^{{λ}_{i}} ) - {P}_{s} ) ] d t$$

The penalty functions γₓ and γ_{λ}, are selected to ensure that the optimal solutions to this penalized problem are strictly interior, that is they strictly satisfy the constraints posed. For the sake of brevity, the following notation can be written in the form:

$${p}_{int} ( {x}^{λ} , λ , {E}^{k} ) = {\int }_{{t}_{0}}^{{t}_{f}} [ {\sum }_{i} ( {γ}_{x} ( - {x}^{{λ}_{i}} ) + {γ}_{x} ( {x}^{{λ}_{i}} - {E}_{i}^{+} ) ) + {\sum }_{i} {γ}_{λ} ( {λ}_{i} ) + {\sum }_{i} {γ}_{x} ( {λ}_{i} {p}_{c , i}^{+} ( {x}^{{λ}_{i}} ) - {C}_{i}^{r} ( t ; {E}^{k} ) ) + {γ}_{x} ( {\sum }_{i} {λ}_{i} {p}_{c , i}^{+} ( {x}^{{λ}_{i}} ) - {P}_{s} ) ] d t$$

Using a variable change, the mixed interior exterior penalized optimal control problem can be written in the form as follows:

$${min}_{v} M ( ϕ ( v ) , {E}^{k} , ε ) = {\int }_{{t}_{0}}^{{t}_{f}} price {\sum }_{i} {p}_{c , i}^{+} ( {x}^{ϕ ( {v}_{i} )} ) ϕ ( {v}_{i} ) d t + ε {p}_{i n t} ( {x}^{ϕ ( v )} , ϕ ( v ) , {E}^{k} )$$

According to an embodiment, an approach based on Pontryagin's maximum principle can be used to solve the optimal control problem without constraint. The solution of the lower bound computation solves a sequence of optimal control problems without constraints. To solve this sequence, an approach based on Pontryagin's maximum principle (PMP) can be used. Therefore first the Hamiltonian H of the problem is defined as follows:

$$H ( {x}^{ϕ ( v )} , ϕ ( v ) , p , {E}^{k} , ε ) = price {\sum }_{i} {p}_{c , i}^{+} ( {x}^{ϕ ( {v}_{i} )} ) ϕ ( {v}_{i} ) + ε {\sum }_{i} ( {γ}_{x} ( - {x}^{ϕ ( {v}_{i} )} ) + {γ}_{x} ( {x}^{ϕ ( {v}_{i} )} - {E}_{i}^{+} ) ) + ε {\sum }_{i} {γ}_{λ} ∘ ϕ ( {v}_{i} ) + ε {\sum }_{i} {γ}_{x} ( ϕ ( {v}_{i} ) {p}_{c , i}^{+} ( {x}^{ϕ ( {v}_{i} )} ) - {C}_{i}^{r} ( t ; {E}^{k} ) ) + {εγ}_{x} ( {\sum }_{i} ϕ ( {v}_{i} ) {p}_{c , i}^{+} ( {x}^{ϕ ( {v}_{i} )} ) - {P}_{S} ) + {\sum }_{i} {p}_{i}^{T} {f}_{c , i} ( {x}^{ϕ ( {v}_{i} )} , ϕ ( {v}_{i} ) )$$

The PMP states that solving the problem is equivalent to solving the following two-point boundary value problem (TPBVP). Many methods allowing this TPBVP to be solved exist. However, selecting a solution algorithm based on collocation methods allows obtaining a good compromise between computation speed and numerical sensitivity.

The invention also relates to a device for controlling an electric vehicle charging infrastructure implementing the method according to one of the embodiments described above.

The invention is not limited to the embodiments described above by way of example, and that it encompasses variant embodiments.

### EXAMPLE

The features and advantages of the method according to the invention will be clear from reading the application example hereafter.

By way of example, the charging of 9 vehicles with two charging stations of different maximum power is considered. The complete charging problem setting is as follows:

$$\begin{matrix}{n}_{x} = 9 the number of vehicles \\ {n}_{b} = 2 the number of charging stations \\ {P}_{c} = \{ 50 , 22 \} \\ {P}_{S} = 60 \\ Δ T = 10 minutes\end{matrix}$$

$$\begin{matrix}\begin{matrix}{t}_{0 , k} = 0 , & k = 1 , … , {n}_{x}\end{matrix} \\ \begin{matrix}{t}_{f , k} ∈ U ( 14 , 24 ) , & k = 1 , … , {n}_{x}\end{matrix} \\ \begin{matrix}{E}_{k}^{+} ∈ U ( 60 , 80 ) , & k = 1 , … , {n}_{x}\end{matrix} \\ \begin{matrix}{x}_{0 , k} ∈ U ( \frac{{E}_{k}^{+}}{10} , \frac{{E}_{k}^{+}}{5} ) , & k = 1 , … , {n}_{x}\end{matrix} \\ \begin{matrix}{x}_{f , k} ∈ U ( \frac{7}{10} {E}_{k}^{+} , \frac{9}{10} {E}_{k}^{+} ) , & k = 1 , … , {n}_{x}\end{matrix} \\ price = \{ \begin{matrix}0.095 & if t ∈ [ 7 , 9 ) ⋃ [ 18 , 20 ) \\ 0.07 & otherwise\end{matrix}\end{matrix}$$

with U(x, y) the uniform distribution of [x, y].

From this example with 9 vehicles and 2 different charging stations, multiset MS(C_{ad}, m_{ad}) can be written:

MS(C_{ad}, m_{ad})=MS({50}, 1) [symbol] MS({22}, 1) [symbol] MS({0}, 7)

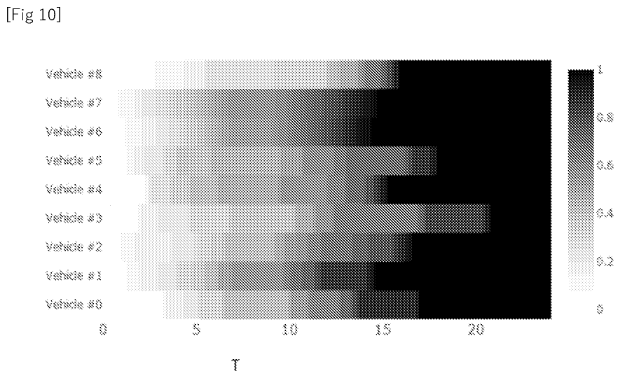

In order to assess the size of the combinatorial problem, the cardinality of the set of permutations perm(nₓ, MS(C_{ad}, m_{ad})) needs to be checked. In this case, the result is exactly the number of permutations of 2 elements among 9, i.e. 72. The optimization problem solved in 24 hours with a switching time T of 10 minutes gives a branch and a tree with 726×24 nodes. Using the Branch and Bound algorithm described, the optimal solution was found at the end of the depth-first search procedure. With this method, only 72×144 nodes have been explored. In this case, the Branch and bound algorithm converges after exploring 72×144 nodes. Its rate of convergence is thus logarithmic relative to the size of the tree. FIG. 9 shows the strategy that consists in switching at nearly each time step the charging vehicles. This figure shows, by way of example, the charging powers as a function of time, and for each of the 9 vehicles. In this figure, the x-axis represents time in hours and the y-axis represents the 9 vehicles, denoted by Vehicle #0 to Vehicle #8. The right-hand side of the figure shows the grey scale representing the intensity of the electrical power applied to each vehicle. This method allows recharging of the vehicles with the last departure time (vehicles 2 and 6 for example) at a rather low power and therefore with a higher efficiency. FIG. 10 shows the evolution of the state of charge of the batteries of the vehicles as a function of time. It is noted that the device allows to achieve charging of the batteries of the 9 vehicles denoted by Vehicle #0 to Vehicle #8 according to the intrinsic characteristics of their batteries. On the right-hand side, a bar with grey scales represents the state of charge of the batteries of the vehicles.

1-15. (canceled)

16. A method for controlling charging with a charging infrastructure charging vehicles, each vehicle being equipped with at least one rechargeable battery, the charging infrastructure comprising at least one charging station connected to an electric distribution network, at least two parking spaces for the vehicles and at least one electric connection of the at least one charging station to at least one vehicle parked in one of the at least two parking spaces, and a number of the charging stations being smaller than a number of parking spaces, the method comprising:
using a set of parameters of the electric vehicles selected from among an initial charge level of at least one battery, a required charge level at an end of charging of the at least one battery, and model of the at least one battery, a set of parameters of the infrastructure selected from a waiting time in a queue of parked vehicles to be charged, electric characteristics of the at least one charging station, at least one of maximum power and efficiency of the charging station, a connection time of the at least one connection being connected to a vehicle, and electrical parameters selected from an electric capacity of the electric distribution network, available local electrical power, a selling price for electricity from the electrical distribution network supplied from the at least one charging station to the electrical distribution network and a purchase price for supplying electricity from the electrical network to the charging station; and
charging at least one vehicle according to a charging sequence comprising at of charging at least one vehicle with a charging sequence for the at least one vehicle with a cost being minimized by at least one element of the sets of parameters.

17. A method as claimed in claim 16, wherein a controlled source of electricity is solar or wind power.

18. A method as claimed in claim 16, wherein the model of the at least one battery is expressed as an open-circuit voltage of the battery, an internal resistance of the battery, and charge of charging the battery model is performed.

19. A method as claimed in claim 17, wherein the battery model is expressed as an open-circuit voltage of the battery, an internal resistance of the battery, and how charging the battery model if performed.

20. A method as claimed in claim 16, wherein the infrastructure comprises automatic recognition of at least one vehicle arriving at one of the parking spaces.

21. A method as claimed in claim 18, wherein the infrastructure comprises automatic recognition of at least one vehicle arriving at one of the parking spaces.

22. A method as claimed in claim 19, wherein the infrastructure comprises automatic recognition of vehicles arriving at the parking spaces.

23. A method as claimed in claim 16, wherein the infrastructure comprises remote communication with the at least one vehicle to be charged.

24. A method as claimed in claim 17, wherein the infrastructure comprises remote communication with at least one vehicle to be charged.

25. A method as claimed in claim 18, wherein the infrastructure comprises remote communication with at least one vehicle to be charged.

26. A method as claimed in claim 19, wherein the infrastructure comprises remote communication with at least one vehicle.

27. A method as claimed in claim 16, wherein at least one of the at least one connection to a vehicle is made automatically.

28. A method as claimed in claim 16, wherein the sequence of charging is determined upon identification of a new vehicle to be charged on arrival of a vehicle in one of the parking spaces or prior to arrival by remote connection or a predetermined schedule.

29. A method as claimed in claim 28, comprising steps of upon identification of a new vehicle to be charged upon departure of a charged vehicle:
a. determining at least one of the elements of the set of parameters of the infrastructure;
b. determining at least one of the elements of the set of parameters of the electrical energy; and
c. for each at least one vehicle comprising steps of:
i. determining at least one element of the set of parameters of the vehicle to be charged;
ii. determining at least one control parameter for each step of charging, the control parameter comprising at least one of duration and electrical power value for charging the at least one electric vehicle to be charged, and the electrical power can be either charging or discharging; and
d. charging each of the at least one vehicle by successively connecting each at least one vehicle parked in one of the parking spaces to a charging station.

30. A method as claimed in claim 16, comprising optimizing charging according to profiles, cost of purchase, and sale of the electrical energy from the network.

31. A method as claimed in claim 16, comprising adjusted charging according to at least one of traffic conditions and a schedule.

32. A method as claimed in claim 16, adjusting charges according to at least one of statistical and stochastic profiles of at least one of the set of parameters.

33. A method as claimed in claim 16, wherein charging is adjusted according to machine learning logic.

34. A method as claimed in claim 16, wherein minimization performed by a cost function using a tree exploration method.

35. A device for controlling charging vehicles, using the method as claimed in claim 16.
